(19) United States
(12) Patent Application Publication
(10) Pub. No.: US 2016/0116513 A1
(43) Pub. Date: Apr. 28, 2016

(54) METER MANAGER FOR AUTOMATED DEMAND RESPONSE IN A MULTI-SITE ENTERPRISE

(71) Applicant: Honeywell International Inc., Morristown, NJ (US)

(72) Inventors: Ripunjeet Dutta, Bangalore (IN); Barnali Chetia, Bangalore (IN); Ajo Paul, Bangalore (IN); Gerald Walter, Cleveland, OH (US); Bandi Swamy, Bangalore (IN); Ronald Chapek, Independence, OH (US)

(21) Appl. No.: 14/526,193

(22) Filed: Oct. 28, 2014

(51) Int. Cl. G01R 21/00; G05B 15/02; G05F 1/66

(52) U.S. Cl. CPC G01R 21/00; G05F 1/66; G05B 15/02

(57) ABSTRACT

A system for obtaining energy data from a large number of sites. Each of the sites may generally have one meter. A meter manager may be designed to receive energy data from virtually all of the meters at the sites. The energy data may be collected at intervals, and go to a supervisory system. Energy data may be stored and sent to a meter server in the event of a communication loss. The energy data from the large number of sites may be received in a seamless manner at a certain frequency and be aggregated. The meter manager may provide an interface for integration with the meters. The energy data may be provided to a building automation supervisor. The data may be stored in a history database of the supervisor. The present system may be designed to facilitate effecting an adjustment of energy usage relative to a demand response situation.

### BACKGROUND

The present disclosure pertains to monitoring energy and particularly to energy use by numerous entities.

### SUMMARY

The disclosure reveals a system for effectively obtaining energy data from a large number of sites. Each of the sites may typically have one meter. A meter manager may be designed to efficiently receive energy data from virtually all of the meters at the sites. The energy data may be collected at intervals, and go to a supervisory system. Storage of energy data may be effected and sent to a meter server in the event of a communication loss. The energy data from the large number of sites may be received in a seamless manner at a high frequency and aggregated. The meter manager may provide an interface for integration with the meters. The energy data may be provided to a building automation supervisor. The data may be stored in a history database of the supervisor. The efficient and quick access of energy data from the sites may facilitate effecting an adjustment of energy usage relative to a demand response situation.

### BRIEF DESCRIPTION OF THE DRAWING

FIG. 1 is a diagram of a meter manager for an automated demand response in a multi-site enterprise.

### DESCRIPTION

The present system and approach incorporates one or more processors, computers, controllers, user interfaces, wireless and/or wire connections, and/or the like, in an implementation described and/or shown herein.

This description may provide one or more illustrative and specific examples or ways of implementing the present system and approach. There may be numerous other examples or ways of implementing the system and approach.

The present meter manager may be a supervisor which applies an approach to manage the task of receiving meter data from the site energy meters of a multi-site enterprise and then to forward aggregated data to the aggregator. The issues of loading a building automation supervisor may be eliminated and the meter manager may provide an interface for the integration with the energy meters.

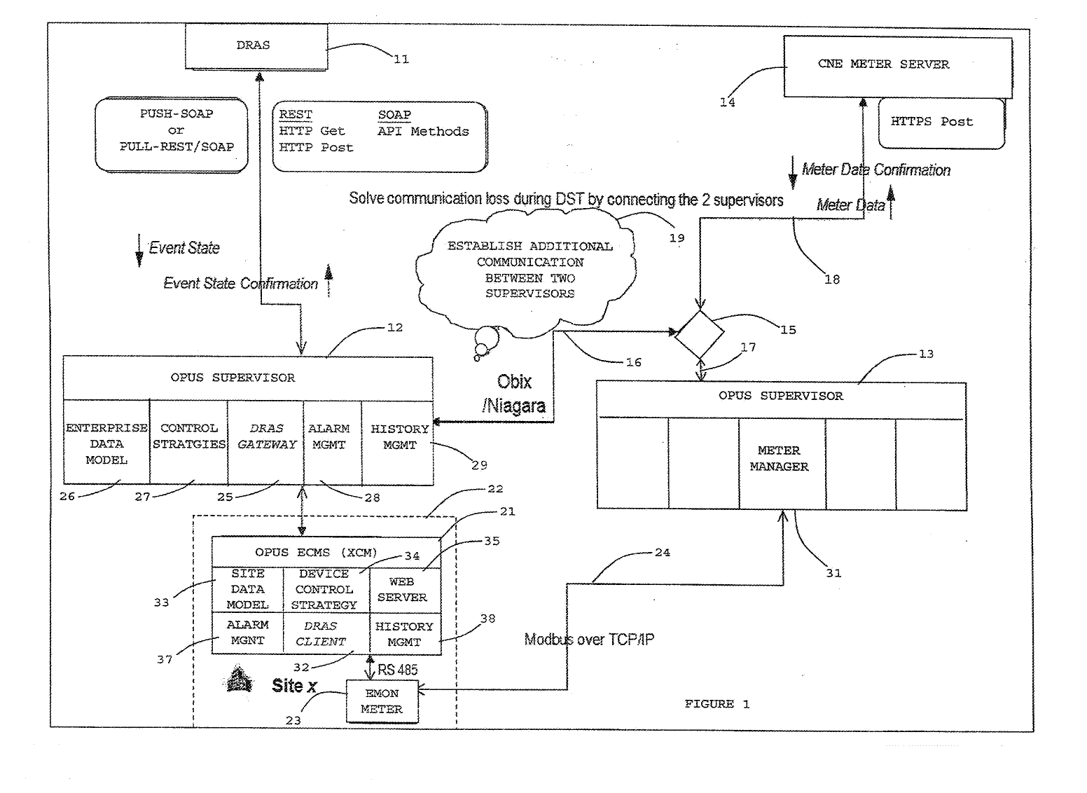

FIG. 1 is a diagram of a meter manager for an automated demand response in a multi-site enterprise. An event state may be provided by demand response automated system (DRAS) 11 to an Opus™ supervisor 12. An event state confirmation may be provided by supervisor 12 to demand response automation server 11. Meter data may be provided by supervisor 12 and/or Opus supervisor 13 to a CNE meter server 14. Meter data confirmation may be provided by meter server 14 to supervisor 12 and/or supervisor 13. Meter data and a meter data confirmation may pass through a junction or summer 15. The data and confirmation from junction 15 to supervisor 12 may be via an oBIX/Niagara™ network of line 16. Communication between two supervisors 12 and 13 may be additionally established via a cloud 19. A connection between junction 15 and supervisor 13 may be via the oBIX/Niagara network of line 17. A connection between server 14 and junction 15 may be via a line 18. One goal is to establish additional communication between supervisors 12 and 13. Another goal is to solve a communication loss during DST (daylight saving time) by connecting supervisors 12 and 13.

An output of supervisor 12 may go to an Opus ECMS (XCM) (site supervisory controller) 21 at a site 22. A two-way communication may occur between ECMS 21 and an Emon™ meter 23 via an RS-485 connection. A two-way communication may occur on a Modbus (a serial communications protocol network) over a TCP/IP (transmission control protocol/Internet protocol) line 24 between meter 23 and supervisor 13.

A significant component of supervisor 12 may be a DRAS gateway 25. Other components of supervisor 12 may incorporate an enterprise data model 26, control strategies 27, alarm management 28 and history management 29. A significant component of supervisor 13 may be a meter manager 31.

A significant component of ECMS 21 of a site 22 may be a DRAS client 32. Other components of ECMS may incorporate a site data model 33, a device control strategy 34, a web server 35, alarm management 37 and history management 38.

Automated demand response (ADR) may be an energy management strategy which seeks to modify energy usage based on the current overall demand relative to a utility or consumer. The strategy may be implemented manually (via an e-mail or phone notification from utility or other) or automatically (via an automated web service notification).

The automated demand response (Opus ADR) solution for multi-site customers of Novar™ may require handling a large number of sites located across the North America. These sites may be installed with energy meters (EMs) which send critical energy data (kilowatt data) at regular intervals at a high frequency of every one minute to the supervisory system which acts as a building automation supervisor (Opus building automation supervisor). The Opus building automation supervisor (OBAS) may receive the critical energy data from the large number of customer sites in addition to the building automation system data such as histories, alarms, and so forth. As the scale of a multi-site enterprise increases, the number of energy meters (EMs) that must be handled may greatly increase. Generally, a single site may have just one energy meter (EM); however, an enterprise with thousands of sites may need to handle critical energy data (kW) from many thousands of energy meters. The critical energy data (kW) from a large number of meters may have to be received in a seamless manner at a higher than normal frequency and aggregated at the building automation supervisor and sent to the aggregator for responding to a load curtailment request relative to a demand response event.

The handling of huge kW data and processing for aggregation may make the building automation supervisor performance intensive and result in performance deterioration. From a compliance standpoint, the building automation supervisor may also need to retain and preserve energy data up to a year of a timeframe. These factors may impact the performance of the building automation supervisor and degrade the performance of the overall building automation system (BAS) as virtually all of the building subsystems may be integrated, monitored and controlled by the building automation supervisor.

The tasks, or responsibilities, of the meter manager may incorporate providing: 1) a user interface for integrating the meters at the sites of a multi-site enterprise; 2) a capability to receive critical energy data (kW) from the sites of the multi-site enterprise; 3) a pull mechanism to receive the energy data (kW) at regular intervals at a high frequency such as of every one minute; 4) a mechanism to aggregate the meter data (kW) from the sites of a multi-site enterprise; 5) a mechanism to push the aggregated data to the aggregator; and 6) a mechanism for fault tolerance by using the energy data validated at the meter manager and Opus building automation system OBS level thereby reducing any chances of failure.

In the multi-site environment, the individual sites may installed with energy meters which send data at regular intervals to the Opus meter manager (OMM) in addition to the Opus building automation supervisor (OBAS). The deployment scenario for automated demand response may involve the Opus building automation system supervisor (OBS), meter manager, site supervisory controllers (XCMs), energy meters and field controllers (FCs).

The meter manager may have a mechanism to connect to a live meter and collect the meter interval data and store the same in the supervisor's history database. This process may be done for virtually every meter configured in the supervisor.

The meter manager may provide the provision for configuring and adding one or more energy meters (EMs) in the in a configuration interface. The meter manager may support communicating with meters over a Modbus protocol network. The meter manager may set the meter time to the current UTC (coordinated universal time) with +/−offset of the meter's time zone.

The meter manager may calculate a pulse multiplier of the meter and persist it. The meter manager may have the capability to read the current interval of the meters of the multi-site enterprise and persist it. The meter manager may read the current time zone of the meters and persist it; also, the meter manager may have the capability to modify the same. The meter manager may read the meter interval data at regular intervals which is every one minute, which may be regarded as a high frequency. The intervals may have other magnitudes. During a communication loss, the meter manager may recover from the communication loss with the meter and collect at least the past one hour of lost data. The meter manager may sync with the system time every 24 hours.

During the daylight saving time turnover (DST), the meter manager may receive meter data from the energy meters from the sites located at different time zones after a load curtailment takes place. As the clock may go back by an hour at 2 AM (to 1 AM), the data in the energy meter for the changeover time (one hour, 1 AM-2 AM), do not necessarily get buffered. In order to eliminate the risk of any loss of critical energy data (kW), the meter data may be collected as energy data or logs at the building automation supervisor through the site supervisory controllers (XCMs) connected to the meters through an RS-485 network. These meter data logs in turn may be imported to the meter manager from the Opus building supervisor through the communication networks (e.g., oBIX/Niagara network). In the event of a communication loss, to prevent loss of critical energy data, loss of money and possible penalty, the meter manage may receive the energy logs from the Opus building automation system (BAS) supervisor (OBS) and then send them to the meter server.

The meter manager may provide unique capabilities for integrating with the site energy meters of a multi-site enterprise, receiving (pulling) energy data at regular intervals, aggregating energy data, and pushing to the aggregator.

To recap, a meter manager system may incorporate a building automation supervisor having a processor and a meter manager, and a multi-site enterprise having sites with energy meters. The meter manager may incorporate one or more items of a group consisting of a user interface, a receiver for critical energy data, a pull mechanism, an aggregating mechanism, a push mechanism, and a fault tolerance mechanism. The user interface may integrate energy meters at the sites. The receiver may receive the critical energy data from the sites. The pull mechanism may receive energy data at regular intervals at a frequency. The aggregating mechanism may aggregate meter data from the sites. The push mechanism may push the aggregated meter data to an aggregator. The fault tolerance mechanism may use energy data validated at a meter manager level or a supervisor level.

The energy meters of the sites may send data at regular intervals to the meter manager and the building automation supervisor.

The meter manager may read meter interval data at a rate of intervals, which is every one or less minutes.

The system may further incorporate a deployment scenario for an automated demand response. The deployment scenario may involve the building automation supervisor, the meter manager, site supervisory controllers, energy meters and/or field controllers.

The meter manager may incorporate a mechanism to connect to each energy meter, collect meter interval data, and store the data in a history database of the building automation supervisor.

The meter manager may incorporate a configuration interface. The meter manager may configure and add one or more energy meters to the configuration interface.

The meter manager may communicate with the energy meters via a network.

The meter manager may set time of a meter according to coordinated universal time (UTC) including offset relative to a time zone of the meter.

The meter manager may calculate a pulse multiplier of a meter, read a current interval of the meters, and read a current time zone of the meters. The meter manager may modify one or more items of a group consisting of the pulse multiplier of a meter, the current interval of the meters, and the current time zone of the meters. The meter manager may persist one or more items of a group consisting of the pulse multiplier of a meter, the current interval of the meters, and the current time zone of the meters.

Data from the meters may be collected as meter data logs at the building automation supervisor via site supervisory controllers (XCMs) connected to the meters through a network. The meter data logs may be sent by the building automation supervisor to a meter server. The meter manager may recover from a communication loss with a meter and collect lost meter data from one or more meter data logs at the meter server.

A meter manager mechanism may incorporate a building automation supervisor having a computer, a demand response automation server connected to the building automation supervisor, a plurality of sites, virtually each site having one or more energy meters, and a meter manager having an interface for integration with the one or more energy meters.

The demand response automation server may provide a demand response event state to the building automation supervisor. In response to a demand response event, an automatic demand response may be an energy management strategy that can modify energy usage by the sites based on current overall energy demand relative to a utility and the sites. The automatic demand response may involve obtaining energy data from the sites.

The energy data may be sent to an aggregator for responding to a demand response load curtailment from the demand response automation server.

The meter manager may receive energy data from the energy meters at intervals of time.

The meter manager may use a fault tolerance mechanism that validates energy data at the building automation supervisor level.

An approach for managing a receipt of data from multiple meters may incorporate providing a computer to operate as a meter manager, integrating meters at a multitude of sites with the meter manager, receiving energy data from the meters at the multitude of sites with the meter manager, receiving the energy data at intervals of time at the meter manager, providing the energy data to a building automation supervisor, validating the energy data at the meter manager or the building automation supervisor to improve fault tolerance, and deploying a scenario for an auto demand response involving the meter manager, the building automation supervisor, availability of energy from a source such as a utility, and/or the energy data for determining a demand response in the scenario.

The approach may further incorporate storing energy data from the meters in a history database of the building automation supervisor. The meter manager may recover from a communication loss with one or more meters by collecting lost energy data for a previous period of time from a site, with the one or more meters, that records data from the one or more meters at a site supervisory controller or field controller or, if available, from the history database of the building automation supervisor.

The meter manager may set time of a meter with UTC including an offset due to a time zone of the meter. The meter manager can receive energy data from meters located at different time zones, even during a daylight saving time turnover, after a load curtailment occurs for a demand response scenario.

The approach may further incorporate configuring and adding one or more meters with the meter manager for connection and providing energy data to the meter manager.

In the present specification, some of the matter may be of a hypothetical or prophetic nature although stated in another manner or tense.

Although the present system and/or approach has been described with respect to at least one illustrative example, many variations and modifications will become apparent to those skilled in the art upon reading the specification. It is therefore the intention that the appended claims be interpreted as broadly as possible in view of the related art to include all such variations and modifications.

What is claimed is:

1. A meter manager system comprising:
a building automation supervisor having a processor and a meter manager; and
a multi-site enterprise having sites with energy meters; and
wherein the meter manager comprises one or more items of a group consisting of a user interface, a receiver for critical energy data, a pull mechanism, an aggregating mechanism, a push mechanism, and a fault tolerance mechanism; and
wherein:
the user interface integrates energy meters at the sites;
the receiver receives the critical energy data from the sites;
the pull mechanism receives energy data at regular intervals at a frequency;
the aggregating mechanism aggregates meter data from the sites;
the push mechanism pushes the aggregated meter data to an aggregator; and
the fault tolerance mechanism uses energy data validated at a meter manager level or a supervisor level.

2. The system of claim 1, wherein the energy meters of the sites send data at regular intervals to the meter manager and the building automation supervisor.

3. The system of claim 1, wherein the meter manager reads meter interval data at a rate of intervals, which is every one or less minutes.

4. The system of claim 1, further comprising a deployment scenario for an automated demand response.

5. The system of claim 4, wherein the deployment scenario involves the building automation supervisor, the meter manager, site supervisory controllers, energy meters and/or field controllers.

6. The system of claim 1, wherein the meter manager comprises a mechanism to connect to each energy meter, collect meter interval data, and store the data in a history database of the building automation supervisor.

7. The system of claim 1, wherein:
the meter manager comprises a configuration interface; and
the meter manager configures and adds one or more energy meters to the configuration interface.

8. The system of claim 1, wherein the meter manager communicates with the energy meters via a network.

9. The system of claim 1, wherein the meter manager sets time of a meter according to coordinated universal time (UTC) including offset relative to a time zone of the meter.

10. The system of claim 1, wherein:
the meter manager calculates a pulse multiplier of a meter, reads a current interval of the meters, and reads a current time zone of the meters;
the meter manager can modify one or more items of a group consisting of the pulse multiplier of a meter, the current interval of the meters, and the current time zone of the meters; and
the meter manager persists one or more items of a group consisting of the pulse multiplier of a meter, the current interval of the meters, and the current time zone of the meters.

11. The system of claim 1, wherein:
data from the meters are collected as meter data logs at the building automation supervisor via site supervisory controllers (XCMs) connected to the meters through a network;
the meter data logs are sent by the building automation supervisor to a meter server; and
the meter manager can recover from a communication loss with a meter and collect lost meter data from one or more meter data logs at the meter server.

12. A meter manager mechanism comprising:
a building automation supervisor comprising a computer;
a demand response automation server connected to the building automation supervisor;
a plurality of sites, virtually each site having one or more energy meters; and
a meter manager having an interface for integration with the one or more energy meters; and
wherein:
the demand response automation server can provide a demand response event state to the building automation supervisor;
in response to a demand response event, an automatic demand response is an energy management strategy that can modify energy usage by the sites based on current overall energy demand relative to a utility and the sites; and
the automatic demand response involves obtaining energy data from the sites.

13. The mechanism of claim 12, where the energy data are sent to an aggregator for responding to a demand response load curtailment from the demand response automation server.

14. The mechanism of claim 12, wherein the meter manager receives energy data from the energy meters at intervals of time.

15. The mechanism of claim 12, wherein the meter manager uses a fault tolerance mechanism that validates energy data at the building automation supervisor level.

16. A method for managing a receipt of data from multiple meters comprising:
providing a computer to operate as a meter manager;
integrating meters at a multitude of sites with the meter manager;
receiving energy data from the meters at the multitude of sites with the meter manager;
receiving the energy data at intervals of time at the meter manager;
providing the energy data to a building automation supervisor;
validating the energy data at the meter manager or the building automation supervisor to improve fault tolerance; and
deploying a scenario for an auto demand response involving the meter manager, the building automation supervisor, availability of energy from a source such as a utility, and/or the energy data for determining a demand response in the scenario.

17. The method of claim 16, further comprising storing energy data from the meters in a history database of the building automation supervisor.

18. The method of claim 17, wherein the meter manager can recover from a communication loss with one or more meters by collecting lost energy data for a previous period of time from a site, with the one or more meters, that records data from the one or more meters at a site supervisory controller or field controller or, if available, from the history database of the building automation supervisor.

19. The method of claim 16, wherein:
the meter manager can set time of a meter with UTC including an offset due to a time zone of the meter; and
the meter manager can receive energy data from meters located at different time zones, even during a daylight saving time turnover, after a load curtailment occurs for a demand response scenario.

20. The method of claim 16, further comprising configuring and adding one or more meters with the meter manager for connection and providing energy data to the meter manager.
